(19) United States
(12) Patent Application Publication
(10) Pub. No.: US 2025/0239946 A1
(43) Pub. Date: Jul. 24, 2025

(54) Nanopositioning Device with High Thermal Performance

(71) Applicant: The Hong Kong University of Science and Technology, Hong Kong (CN)

(72) Inventors: Berthold JÄCK, Hong Kong (CN); WILWIN, Hong Kong (CN)

(21) Appl. No.: 18/474,323

(22) Filed: Sep. 26, 2023

Related U.S. Application Data
(60) Provisional application No. 63/426,795, filed on Nov. 21, 2022.

(51) Int. Cl. H02N 2/02; H02N 2/04; H02N 2/06; H10N 30/853

(52) U.S. Cl. CPC H02N 2/028; H02N 2/043; H02N 2/06; H10N 30/853

(57) ABSTRACT

A nanopositioning device capable of positioning objects with nanometer scale accuracy is provided. The nanopositioning device includes a carriage component and an actuator coupled to the carriage component through an axle for controlling a position of the carriage component with respect to the actuator precisely. The carriage component includes a front clamp and a rear clamp. The carriage component is displaceable relative to the axle, which is attached to a base. The actuator includes piezoelectric stacks and the axle extended from the piezoelectric stacks to couple to the front clamp and the rear clamp to stick-slip drive the carriage component. The axle includes a plurality of ceramic plates. Each of the plurality of ceramic plates is polished and made of a ceramic material. The plurality of ceramic plates are in contact with the front clamp and the rear clamp to realize a friction interface for driving the carriage component.

### CROSS-REFERENCE TO RELATED APPLICATIONS

This application claims the benefit of the U.S. Provisional Patent Application No. 63/426,795, filed on Nov. 21, 2022, which is incorporated by reference herein in its entirety.

### FIELD OF THE INVENTION

The present disclosure generally relates to the field of precision engineering. In particular, the present disclosure relates to a nanopositioner with reliable operation under ambient conditions and in extreme environments.

### BACKGROUND OF THE INVENTION

Nanopositioners have emerged as critical tools in many scientific and commercial fields due to their capability to position objects with nanometer accuracy. Nanopositioners are instrumental in scanning probe microscopes, optical microscopes, life science instrumentation, and other devices for the semiconductor and data storage industry. Most existing nanopositioners operate on the stick-slip mechanism, where a piezoelectric component drives a dynamic translator. The translator's motion results from the alternating slipping or sticking action between two elements actuated by the piezoelectric element's extension and contraction [1], [2].

In this operation, an axis is secured to a base and coupled to a carriage component through a friction interface, which is formed between the surfaces of the axis and carriage. The piezoelectric stack and metal rod, constituting the axis, extend or contract upon voltage application. At a slower rate, the finterial force is less than the maximum static friction force, causing the clamp to move with the axis. However, when the piezoelectric element extends or contracts rapidly, the inertial force of the carriage exceeds the static friction force, leading to a slip between the clamp and the axis. The subsequent execution of this stick-and-skip mechanism facilitates the displacement of the carriage along a linear axis.

Many applications also require the use of a “closed-loop” position sensor for feedback and control. To date, piezoresistive or film-type elements are often employed. While their integration is cost-efficient, these types of sensors offer comparably low measurement accuracy and cause energy dissipation during operation. By contrast, the capacitance sensors offer unrivaled accuracy, long-term stability and linearity while being essentially free of energy dissipation. This makes them particularly useful for application under extreme conditions and in which energy dissipation must be avoided, such as cryogenic environments.

The displacement per step of stick-and-slip motion is determined by multiple factors including clamping force, friction coefficients, and load weight and these parameters are highly susceptible to environmental conditions such as temperature and pressure.

Operating a stick-slip drive in vacuum and cryogenic environments poses additional challenges. The piezoelectric actuator's performance decreases at low temperatures, requiring an increased drive voltage for the same linear displacement. For instance, at cryogenic temperatures of 4K, the piezoelectric actuator can only reach 5% of the displacement at room temperature. This results in an increased power dissipation, which is proportional to the square of the drive voltage, and potential detrimental heating effects. Thermal contraction can change the spatial dimensions of the nanopositioner components, affecting the contact force between the carriage and the base at the friction surface. Moreover, absent the lubricating effect of air and moisture, the friction between carriage and base typically increases in vacuum. Hence, achieving a consistently reliable nanopositioner across varying environmental conditions poses a significant challenge.

Therefore, the material choice becomes particularly critical at cryogenic temperatures. Many materials, especially electrically insulating materials such as alumina (Al₂O₃), poorly conduct heat at these temperatures and can prevent the efficient thermalization of an object to the temperature of the environment, especially at significantly low temperatures below 1K. Additional measures for efficient heat transfer, such as installing external copper braids are required.

Existing commercial nanopositioners face several shortcomings. They rely on an alumina axis that is rigidly connected to a fixed base via the piezoelectric element. When the surface roughness of the alumina axis is not optimized to nanometer scale roughness, a thin surface coating to reduce friction is required. However, such coatings, which are typically made of graphite or molybdenum disulfide, can absorb moisture and inhibit a reliable motion under vacuum or cryogenic conditions, when surface-adsorbed moisture freezes.

Commercial nanopositioners are not well-suited for operation over a wide temperature range due to a mismatch in the materials' thermal expansion coefficient. This leads to unreliable operation at cryogenic temperatures, in particular at low temperatures below 1K.

Existing position read-out mechanisms, based on electrical resistance readout, dissipate significant electric power, limiting their use under cryogenic conditions. The footprint of commercially available nanopositioners is significantly increased when the read-out mechanism is included, potentially excluding its use in space-constrained applications.

In view thereof, there is a need in the art for a nanopositioner, which offers a reliable operation under ambient conditions and in extreme environments, efficient heat transfer across the positioning device, and an accurate and dissipation-free position read-out. Furthermore, other desirable features and characteristics will become apparent from the subsequent detailed description and the appended claims, taken in conjunction with the accompanying drawings and this background of the disclosure.

### SUMMARY OF THE INVENTION

Provided herein is a nanopositioner with reliable operation under ambient conditions and in extreme environments.

In certain aspects of the present disclosure, a nanopositioning device capable of positioning objects with nanometer scale accuracy is provided. The nanopositioning device includes a carriage component and an actuator coupled to the carriage component for controlling a position of the carriage component with respect to the actuator precisely. The carriage component includes a front clamp and a rear clamp. The actuator includes piezoelectric stacks and an axle extended from the piezoelectric stacks to couple to the front clamp and the rear clamp to stick-slip drive the carriage component. The axle includes a plurality of ceramic plates. Each of the plurality of ceramic plates is polished and made of a ceramic material. The plurality of ceramic plates are in contact with the front clamp and the rear clamp to realize a friction interface for driving the carriage component.

In an embodiment, the plurality of ceramic plates is adhesively attached to the axle for reducing a dissipative friction loss in a stick-slip motion and enhancing a thermal conductivity.

In an embodiment, the axle and the carriage component are made of materials having a substantially identical thermal expansion coefficient such that a pressing force of the carriage component on the plurality of ceramic plates and the axle is temperature independent.

In an embodiment, the plurality of ceramic plates are flat solid plates having a thickness of ≤250 μm. The axle has a diameter of 2 mm to 10 mm, thereby a mismatch in thermal expansion coefficient between the plurality of ceramic plates and the axle is negligible such that a friction coefficient of the friction interface formed by the carriage component and the plurality of ceramic plates becomes temperature-independent.

In an embodiment, the plurality of ceramic plates, the axle, and the carriage components are made of materials having a substantially high thermal conductivity to afford an efficient heat transfer across the nanopositioning device.

In an embodiment, the front clamp and the rear clamp each includes a plurality of internal surfaces. Each of the plurality of internal surfaces is a polished metal surface for interfacing with the plurality of ceramic plates to form the friction interface.

In an embodiment, the nanopositioning device further includes a base and one or more metallic rods for performing positional feedback. The base includes one or more rod sockets and a capacitance sensor. The front clamp and the rear clamp include one or more through holes arranged at positions aligned with the one or more rod sockets for accommodating the one or more metallic rods. The capacitance sensor is configured to determine a geometric capacitance between the one or more metallic rods and the carriage component for calculating a relative position of the carriage component with respect to the base.

In an embodiment, each of the one or more metallic rods is a vertical rod with a circular or a polygonic cross-section.

In an embodiment, the capacitance sensor is a sigma-delta (Σ-λ) capacitance-to-digital converter.

In an embodiment, the one or more metallic rods are fixedly connected to the one or more rod sockets via an insulating plate for electrically insulating the one or more metallic rods from the base or the base plate. The insulating plate is a ceramic separator made of Aluminum nitride (AlN) or sapphire.

In an embodiment, the base further includes a base body and a base plate. The piezoelectric stacks are glued or adhesively attached to the base plate. The insulating plate is adhesively attached to the base body or the base plate inside the one or more rod sockets.

In an embodiment, the base body further includes a plurality of cable slots arranged for connecting a plurality of cables to the piezoelectric stacks. The piezoelectric stacks are configured to receive a sawtooth voltage signal.

In an embodiment, the carriage component is configured to follow a movement of the axle when a slow rising or a slow decreasing voltage signal is applied to the piezoelectric stacks. The axle is configured to slip to cause a stick-slip motion of the carriage component with respect to the base body when a fast rising or fast decreasing voltage signal is applied to the piezoelectric stacks.

In an embodiment, the axle further includes extensions extending from a bottom end of the axle in a direction parallel to the axle. The extensions are thin metallic sheets rigidly connected to the base plate to realize a screw joint between the axle and the base.

In an embodiment, the nanopositioning device further includes a base being a support structure placed below the carriage component. The carriage component, the axle, and the base are made of a metallic material selected from the group consisting of Molybdenum (Mo), beryllium copper (BeCu) and phosphor bronze (PhBr); and wherein the ceramic material is AlN or sapphire.

In an embodiment, the friction interface between the carriage component and the axle enables a bi-directional linear inertial motion of the carriage component relative to the base using a stick-slip mechanism.

In an embodiment, the axle is a cuboid axle with a rectangular cross-section and the axle can be inserted into a rectangular hole gap formed when the front clamp and the rear clamp abut against each other.

In an embodiment, the front clamp and the rear clamp each comprises two screw slots. The front clamp and the rear clamp are adjustably joined by two spring-loaded screws through the screw slots for controlling a clamping force exerted by the carriage component on the axle.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. Other aspects and advantages of the present invention are disclosed as illustrated by the embodiments hereinafter.

### BRIEF DESCRIPTION OF THE DRAWINGS

The appended drawings contain figures to further illustrate and clarify the above and other aspects, advantages, and features of the present disclosure. It will be appreciated that these drawings depict only certain embodiments of the present disclosure and are not intended to limit its scope. It will also be appreciated that these drawings are illustrated for simplicity and clarity and have not necessarily been depicted to scale. The present disclosure will now be described and explained with additional specificity and detail through the use of the accompanying drawings in which:

FIG. 1 is a perspective view of a nanopositioning device in accordance with certain embodiments of the present disclosure.

FIG. 2 is a top view of the nanopositioning device of FIG. 1.

FIG. 3 is an exploded view of the nanopositioning device of FIG. 1.

FIG. 4 is a cross-sectional view of the nanopositioning device along the axis A-A′ in FIG. 2.

FIG. 5 is an exploded view of another embodiment of the nanopositioning device having a screw joint in accordance with certain embodiments of the present disclosure.

### DETAILED DESCRIPTION OF THE INVENTION

The following detailed description is merely exemplary in nature and is not intended to limit the disclosure or its application and/or uses. It should be appreciated that a vast number of variations exist. The detailed description will enable those of ordinary skilled in the art to implement an exemplary embodiment of the present disclosure without undue experimentation, and it is understood that various changes or modifications may be made in the function and structure described in the exemplary embodiment without departing from the scope of the present disclosure as set forth in the appended claims.

The benefits, advantages, solutions to problems, and any element(s) that may cause any benefit, advantage, or solution to occur or become more pronounced are not to be construed as a critical, required, or essential features or elements of any or all of the claims. The invention is defined solely by the appended claims including any amendments made during the pendency of this application and all equivalents of those claims as issued.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The terms “comprising,” “having,” and “including” or any other variation thereof, are to be construed as open-ended terms (i.e., meaning “including, but not limited to,”) unless otherwise noted. The use of any and all examples, or exemplary language (e.g., “such as”) provided herein, is intended merely to illuminate the invention better and does not pose a limitation on the scope of the invention unless otherwise claimed. No language in the specification should be construed as indicating any non-claimed element as essential to the practice of the invention.

Unless otherwise defined, all terms (including technical and scientific terms) used in the embodiments of the present invention have the same meaning as commonly understood by an ordinary skilled person in the art to which the present invention belongs.

The term “substantially identical” as used herein when referring to the thermal expansion coefficient describes two materials having the same or nearly the same thermal expansion coefficient, such that the thermal expansion of the two materials are comparable.

Considering the background, it is desirable to provide a nanopositioner with reliable operation over a wide temperature and pressure range. Particularly, the space technology, the semiconductor industry, and microscopy and quantum sensing require reliable and accurate positioning at the nanometer level in ultra-high vacuum conditions and cryogenic conditions, which may operate at pressures below 1×10⁻⁹ mbar and at temperatures down to −273° C.

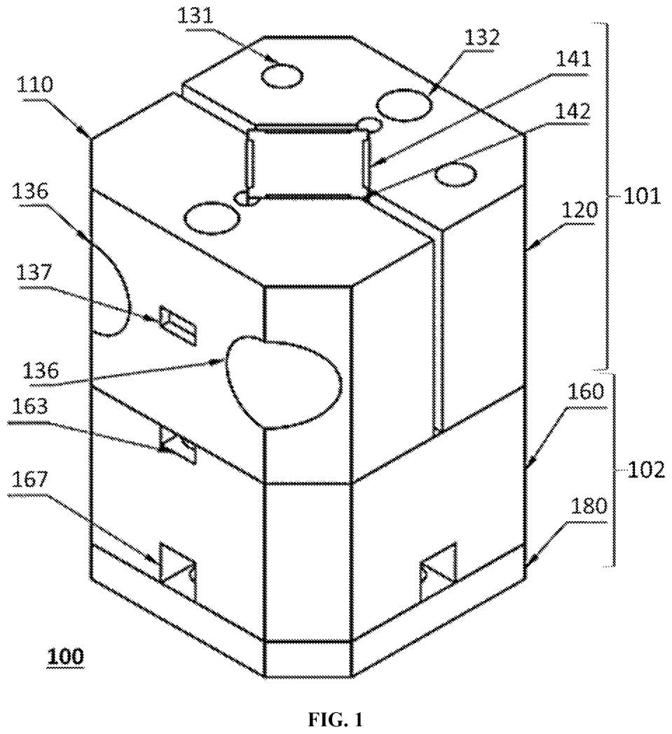

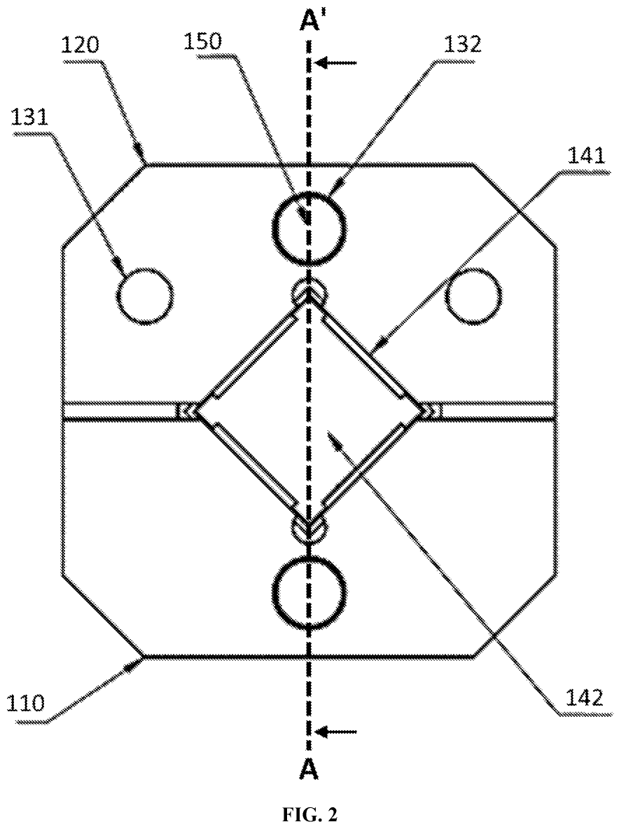

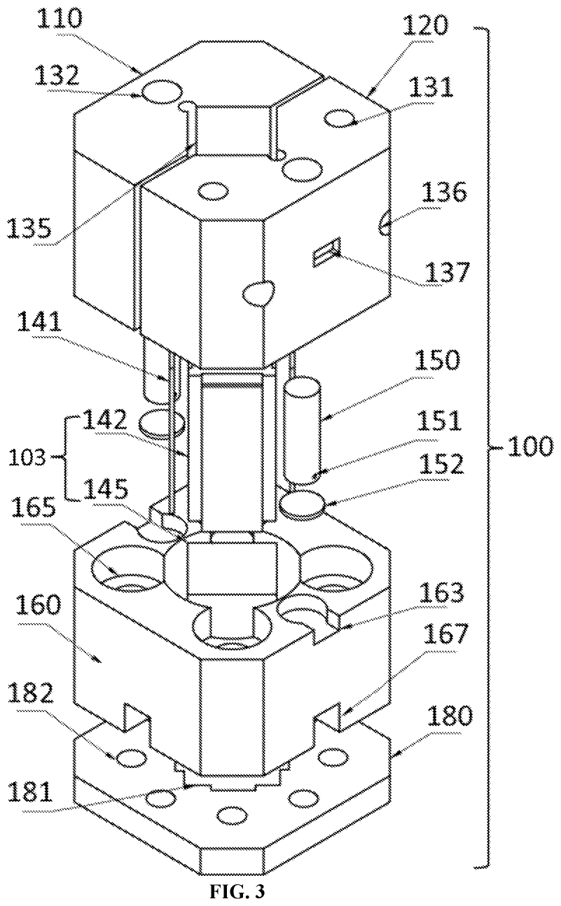

The present disclosure is related to a nanopositioning device 100 capable of positioning objects with nanometer scale accuracy. FIGS. 1 and 2 show a perspective view and a top view of the nanopositioning device 100 according to an embodiment of the present invention. FIG. 3 shows an exploded view of the nanopositioning device 100. The nanopositioning device 100 is based on a stick-slip drive principle capable of operating in a wide temperature range from above room temperature to below 1 K under ambient and ultra-high vacuum conditions. In particular, the geometric dimensions of the nanopositioning device 100, together with the components therein, and the materials from which the nanopositioning device 100 and components fabricated are optimized to maximize the efficient heat transfer across the nanopositioning device 100 and to facilitate the reliable operation of the nanopositioning device 100 at ambient conditions, in ultra-high vacuum conditions, and across a large temperature window ranging from below 1 K to above room temperature.

The nanopositioning device 100 comprises a base 102, an actuator 103, and a carriage component 101 having a front clamp 110 and a rear clamp 120, abutting against each other to form an octagonal shape with a rectangular hole gap. The actuator 103 is coupled to the carriage component 101 for controlling a position of the carriage component 101 precisely, wherein the actuator 103 comprises piezoelectric stacks 145 and an axle 142. The axle 142 is preferably cuboid in shape and is inserted through the rectangular hole gap axially to the base 102, such that the axle 142 extends from the piezoelectric stacks 145 to couple to the front clamp 110 and the rear clamp 120 to stick-slip drive the carriage component 101. Therefore, the carriage component 101 can perform a bi-directional linear inertial motion along a vertical axis defined by the axle 142. In certain embodiments, the carriage component 101 is displaceable relative to the axle 142, which is attached to the base 102. The front clamp 110 and the rear clamp 120 each comprises two screw slots 136. With the screw slots 136, the front clamp 110 and the rear clamp 120 are adjustably joined by two spring-loaded screws (not shown) through the screw slots. In particular, the two spring-loaded screws are screwed into the two screw slots 136 to secure the front clamp 110 to the rear clamp 120. The spring-loaded screws provide a constant force, ensuring that the pressure remains consistent. By adjusting the position of the spring-loaded screws through the screw slots 136, the clamping force exerted by the carriage component 101 on the axle 142 can be controlled. This approach provides a reliable mean for securely mounting the front clamp 110 and the rear clamp 120 of the carriage component 101 while allowing for precise adjustments to achieve the desired level of grip.

The carriage component 101 formed by the front clamp 110 and the rear clamp 120 is in contact with the axle 142 comprising a plurality of ceramic plates 141. In certain embodiments, the axle 142 has a polygonal cross-section. More preferably, the axle 142 is a cuboid axle with a rectangular cross-section and can be inserted into the rectangular hole gap. Each of the plurality of ceramic plates 141 is polished and made of a ceramic material. The plurality of ceramic plates 141 are in contact with the front clamp 110 and the rear clamp 120 to realize a friction interface for driving the carriage component 101. The plurality of ceramic plates 141 are flat solid plates adhesively attached to the axle 142. Preferably, the ceramic material is Aluminum nitride (AlN) or sapphire. Advantageously, the ceramic plates 141 can reduce a dissipative friction loss in a stick-slip motion and enhance a thermal conductivity as compared to using axles entirely made from alumina (amorphous Al₂O₃). As shown in the illustrated embodiments, the plurality of ceramic plates 141 comprises four flat solid plates adhesively attached to four sides of the cuboid axle. Two of the plurality of ceramic plates 141 are in contact with the front clamp 110, and another two of the plurality of ceramic plates 141 are in contact with the rear clamp 120. The axle 142 enables a bi-directional linear inertial motion of the carriage component 101 relative to the base 102 using a stick-slip mechanism, so the carriage component 101 can move along the vertical axis defined by the axle 142. In one embodiment, the axle 142 has a diameter of 2 mm to 10 mm while the plurality of ceramic plates 141 has a thickness of ≤250 μm, a mismatch in thermal expansion coefficient between the plurality of ceramic plates 141 and the axle 142 is negligible such that a friction coefficient of the friction interface formed by the carriage component 101 and the plurality of ceramic plates 141 becomes temperature-independent.

The front clamp 110 and the rear clamp 120 each comprises a plurality of internal surfaces 135. Each of the plurality of internal surfaces 135 is a polished metal surface for interfacing with the plurality of ceramic plates 141 to form a friction interface. In certain embodiments, each of the plurality of internal surfaces 135 has the surface roughness minimized by an electropolishing or mechanical surface treatment. The plurality of internal surfaces 135 and the plurality of ceramic plates 141 collectively form the friction interface between the front clamp 110 (or the rear clamp 120) and the axle 142, wherein the friction force acting on the friction interface can be controlled by adjusting the clamping force exerted by the carriage component 101 on the axle 142 using the spring-loaded screws.

The rear clamp 120 further comprises one or more thread holes 131 for fastening a load to the rear clamp 120 of the carriage component 101. The screw is rotatably inserted into the one or more thread holes 131. The load can be displaced with respect to the base 102, which is a stable platform for the nanopositioning device 100, via a bi-directional motion along the axle 142.

The piezoelectric stacks 145 comprise multiple thin piezoelectric elements stacked together. When a voltage is applied to the piezoelectric stacks 145, each piezoelectric elements will expand or contract slightly. The overall effect of the piezoelectric stacks 145 is an amplified displacement due to the multiple piezoelectric elements working in parallel.

The base 102 is a support structure placed below the carriage component 101. In certain embodiments, the base 102 comprises a base body 160 and/or a base plate 180. The base body 160 and the base plate 180 are mounted together using one or more screws or other connectors through the plural thread holes 182. The piezoelectric stacks 145 are glued or otherwise adhesively attached to the base plate 180 at the piezoelectric stack slot 181. The base body 160 further comprises a plurality of cable slots 167 arranged for connecting a plurality of cables (not shown) to the piezoelectric stacks 145.

In certain embodiments, the piezoelectric stacks 145 are configured to receive a sawtooth voltage signal. When a slow rising or a slow decreasing voltage signal is applied to the piezoelectric stacks 145, the carriage component 101 is configured to follow a movement of the axle 142. On the other hand, when a fast rising or fast decreasing voltage signal is applied to the piezoelectric stacks 145, the length of the piezoelectric stacks 145 will change rapidly. Owing to the inertia of the carriage component 101, the axle 142 will slip to cause a stick-slip motion of the carriage component 101 with respect to the base 102.

With the application of a voltage to the piezoelectric stacks 145, the piezoelectric material is caused to expand or contract, which in turn causes the axle 142 to move up or down. The carriage component 101, to which a load may be attached via the screw holes 131, moves along the axle 142 to allow the load to be precisely positioned.

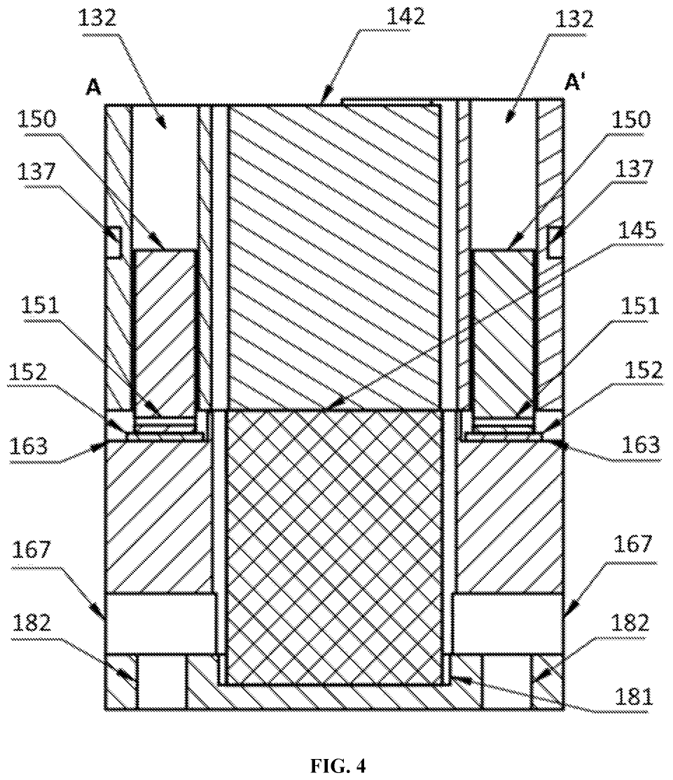

The nanopositioning device 100 further comprises one or more metallic rods 150 for obtaining positional feedback. The front clamp 110 and the rear clamp 120 comprise one or more through holes 132, which allows the one or more metallic rods 150 to be placed within. In the illustrated embodiments, there is one through hole 132 on the front clamp 110, and another through hole 132 on the rear clamp 120. With reference to the cross-sectional view in FIG. 4, the one or more through holes 132 are arranged at positions aligned with the one or more rod sockets 163, which are provided on the base 102. The one or more metallic rods 150 are used to determine the relative positions of the carriage component 101 for the purpose of positioning. In certain embodiments, the geometric capacitance between the carriage component 101 and the one or more metallic rods 150 is determined, which depends on the vertical position of the front clamp 110 and the rear clamp 120. This can be used be used as a position read-out quantity. Particularly, the geometric capacitance (C_{C-R}) is calculated by:

$${C}_{C - R} = \frac{2 πε L}{ln ( \frac{b}{a} )} \qquad [ Eq . 1 ]$$

where:
L is a length of the metallic rod 150 geometrically overlapping with the carriage component 101;
b is a hole diameter of each of the one or more through holes 132; and
a is a rod diameter of each of the one or more metallic rods 150.

Using typical dimensions L=5 mm, b=2.2 mm, ε=8.85×10⁻¹² F·m⁻¹, and a=2 mm, the geometric capacitance is 2.92 pF. The capacitance value depends on the relative position of the carriage component 101 with respect to one or more metallic rods 150 and can be determined by means of an external sensing circuit. In certain embodiments, the capacitance sensor is a sigma-delta (Σ-λ) capacitance-to-digital converter. As an example, the capacitance sensor may be AD7745 or AD7746 which can resolve capacitances as small as 4 aF. The capacitance sensor is a built-in capacitance sensor realized inside the footprint of the nanopositioning device 100. It is apparent that the capacitance sensor may be positioned in other locations other than the base 102. Contact cables are used to connect to the one or more metallic rods 150 at the upper contact cable slot 137 and the lower contact cable slot 151 for capacitance measurement.

Each of the one or more metallic rods 150 is a vertical rod with a circular or a polygonic cross-section. The one or more metallic rods 150 are accommodated in the one or more through holes 132. The surfaces of the one or more metallic rods 150 are electrically isolated with respect to the front clamp 110 and the rear clamp 120 by empty space. At the lowest end of the one or more through holes 132, the one or more metallic rods 150 are also electrically isolated from the base body 160 by an insulating plate 152. In certain embodiments, the one or more metallic rods 150 are fixedly connected to the base 102 at the one or more rod sockets 163 via the insulating plate 152 for electrically insulating the one or more metallic rods 150 from the base 102 or the base plate 180. Particularly, for achieving the electrical insulation, the insulating plate 152 is a ceramic separator made of AlN or sapphire, which are electrical insulators. It is apparent that the insulating plate 152 may be made of other electrical insulators without departing from the scope and spirit of the present disclosure. By using two metallic rods 150, as demonstrated in the illustrated embodiments, a position read-out accuracy of better than 10 nm over a total travel distance of L=5 mm can be achieved. Hence, the disclosed capacitive read-out design affords a superior read-out accuracy, reduced heat dissipation during the read-out process, and a reduced geometrical footprint of the nanopositioning device 100.

A further aspect of the present disclosure provides a high operational performance of the nanopositioning device 100 over wide temperature ranges. The carriage component 101, the axle 142, and the base 102 are made of an identical metallic material selected from the group consisting of Molybdenum (Mo), beryllium copper (BeCu), and phosphor bronze (PhBr). This is to maintain the operational performance of the stick-slip mechanism of the nanopositioning device 100 in the event of temperature changes. Owing to the material specific thermal expansion coefficient, the extent of thermal expansion and contraction of the spatial dimensions of an object depends on its material. In certain embodiments, the carriage component 101, the axle 142, and the base 102 are made of an identical material or materials having a substantially identical thermal expansion coefficient. Therefore, the thermal contraction and expansion has a negligible influence on the spatial dimensions of the carriage component 101, the axle 142, and the base 102. Hence, the pressing force of the carriage component 101 on the plurality of ceramic plates 141 and the axle 142 is independent from the temperature. On the other hand, the plurality of ceramic plates 141 are made of AlN or sapphire. Because the plurality of ceramic plates 141 have a thickness of ≤250 μm, the possible mismatch of their thermal expansion coefficients (e.g., Mo is around 5×10⁻⁶/K and AlN is around 4.5×10⁻⁶/K) can be neglected. This enables the stick-slip mechanism to reliably operate over a wide temperature window from <1 K to beyond room temperature.

A further aspect of the present disclosure provides a high thermal conductivity in the nanopositioning device 100, which makes this device ideally suited for applications that require the efficient removal of excess heat load or the provision of sufficient cooling power across the nanopositioning device 100. Particularly, the plurality of ceramic plates 141, the axle 142, and the carriage components 101 are made of materials having a substantially high thermal conductivity to afford an efficient heat transfer across the nanopositioning device 100. The relatively high thermal conductivity of the materials (Mo, BeCu, and PhBr) facilitates an efficient heat transfer across the nanopositioning device 100. Because the plurality of ceramic plates 141 have a thickness of ≤100 μm, the effect of their comparably poor thermal conductivity at temperatures smaller than 1 K on the overall heat conductivity across the nanopositioning device 100 is minimized. For example, excess heat created by an object attached to the carriage component 101 will be efficiently transported across the complete nanopositioning device 100 to a supporting structure that is rigidly connected to the base plate 180. Hence, the nanopositioning device 100 of the present disclosure is featured with a reliable operation at the lowest temperatures of 100 mK and in processes in which excess heat loads must be removed.

In an embodiment, the rigid connection between the axle 142 and the base 102 is established via an adhesive interface or a screw joint, which is based on thin metallic sheets extending in a direction parallel to the axle 142. The use of a screw joint is advantageous because it realizes a metallic interface between the axle 142 and the base 102 which maximizes the heat transfer, while the thin metallic sheets do not impede the piezoelectric effect of the actuator 103.

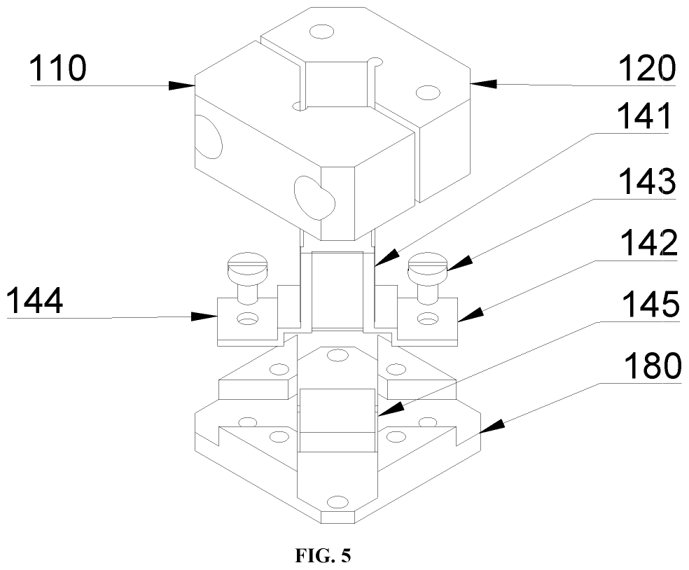

With reference to FIG. 5, another embodiment of the nanopositioning device 100 having a screw joint 143 is provided. The axle 142 further comprises extensions 144 extending from a bottom end of the axle 142 in a direction parallel to the axle 142 with the purpose of providing thermal conductance. Preferably, the extensions 144 can be thin metallic sheets rigidly connected to the base plate 180 through a screw joint 143. This screw joint 143 realizes a metal-to-metal contact, which further maximizes the efficient transfer of heat load across the nanopositioning device 100 from the carriage 101 to the base 102, by comparison to the adhesive interface between the axle 142 and the piezoelectric stacks 145.

Therefore, the nanopositioning device 100 of the present disclosure can achieve reliable operation over a wide temperature range and in and out of ultra-high vacuum conditions. This illustrates the fundamental structure of the nanopositioning device 100 in accordance with the present disclosure. It will be apparent that variants of the above-disclosed and other features and functions, or alternatives thereof, may be combined into many other different methods or apparatuses. The present embodiment is, therefore, to be considered in all respects as illustrative and not restrictive. The scope of the disclosure is indicated by the appended claims rather than by the preceding description, and all changes that come within the meaning and range of equivalency of the claims are therefore intended to be embraced therein.

### REFERENCES

The following references are cited in the specification. Disclosures of these references are incorporated herein by reference in their entirety.
[1] N D. W. Pohl, “Dynamic piezoelectric translation devices,” Review of Scientific Instruments, vol. 58, p. 54-57, 1987, https://doi.org/10.1063/1.1139566.
[2] Ph. Niedermann, R. Emch, P. Descouts, “Simple piezoelectric translation device,” Review of Scientific Instruments, vol. 59, p. 368-369, 1988, https://doi.org/10.1063/1.1140206.

What is claimed is:

1. A nanopositioning device capable of positioning objects with nanometer scale accuracy, comprising:
a carriage component comprising a front clamp and a rear clamp; and
an actuator coupled to the carriage component for controlling a position of the carriage component with respect to the actuator precisely, wherein the actuator comprises piezoelectric stacks and an axle extended from the piezoelectric stacks to couple to the front clamp and the rear clamp to stick-slip drive the carriage component,
wherein:
the axle comprises a plurality of ceramic plates;
each of the plurality of ceramic plates is polished and made of a ceramic material; and
the plurality of ceramic plates is in contact with the front clamp and the rear clamp to realize a friction interface for driving the carriage component.

2. The nanopositioning device of claim 1, wherein the plurality of ceramic plates is adhesively attached to the axle for reducing a dissipative friction loss in a stick-slip motion and enhancing a thermal conductivity.

3. The nanopositioning device of claim 2, wherein the axle and the carriage component are made of materials having a substantially identical thermal expansion coefficient such that a pressing force of the carriage component on the plurality of ceramic plates and the axle is temperature independent.

4. The nanopositioning device of claim 2, wherein the plurality of ceramic plates are flat solid plates having a thickness of ≤250 μm; and wherein the axle has a diameter of 2 mm to 10 mm, thereby a mismatch in thermal expansion coefficient between the plurality of ceramic plates and the axle is negligible such that a friction coefficient of the friction interface formed by the carriage component and the plurality of ceramic plates becomes temperature-independent.

5. The nanopositioning device of claim 2, wherein the plurality of ceramic plates, the axle, and the carriage components are made of materials having a substantially high thermal conductivity to afford an efficient heat transfer across the nanopositioning device.

6. The nanopositioning device of claim 2, wherein the front clamp and the rear clamp each comprises a plurality of internal surfaces, and wherein each of the plurality of internal surfaces is a polished metal surface for interfacing with the plurality of ceramic plates to form the friction interface.

7. The nanopositioning device of claim 1 further comprising a base and one or more metallic rods for performing positional feedback, wherein:
the base comprises one or more rod sockets and a capacitance sensor;
the front clamp and the rear clamp comprise one or more through holes arranged at positions aligned with the one or more rod sockets for accommodating the one or more metallic rods; and
the capacitance sensor is configured to determine a geometric capacitance between the one or more metallic rods and the carriage component for calculating a relative position of the carriage component with respect to the base.

8. The nanopositioning device of claim 7, wherein each of the one or more metallic rods is a vertical rod with a circular or a polygonic cross-section; and wherein the relative position of the carriage is determined based on the geometric capacitance (C_{C-R}) calculated by:
$${C}_{C - R} = \frac{2 πε L}{ln ( \frac{b}{a} )}$$
where:
L is a length of the metallic rod geometrically overlapping with the carriage component;
b is a hole diameter of each of the one or more through holes; and
a is a rod diameter of each of the one or more metallic rods
ε is a dielectric constant.

9. The nanopositioning device of claim 7, wherein the capacitance sensor is a sigma-delta (Σ-Δ) capacitance-to-digital converter.

10. The nanopositioning device of claim 7, wherein the one or more metallic rods are fixedly connected to the one or more rod sockets via an insulating plate for electrically insulating the one or more metallic rods from the base or the base plate, and wherein the insulating plate is a ceramic separator made of Aluminum nitride (AlN) or sapphire.

11. The nanopositioning device of claim 10, wherein the base further comprises a base body and/or a base plate, and wherein the piezoelectric stacks are glued or adhesively attached to the base plate; and wherein the insulating plate is adhesively attached to the base body or the base plate inside the one or more rod sockets.

12. The nanopositioning device of claim 11, wherein the base body or the base plate further comprises a plurality of cable slots arranged for connecting a plurality of cables to the piezoelectric stacks; and wherein the piezoelectric stacks are configured to receive a sawtooth voltage signal.

13. The nanopositioning device of claim 12, wherein the carriage component is configured to follow a movement of the axle when a slow rising or a slow decreasing voltage signal is applied to the piezoelectric stacks; and wherein the axle is configured to slip to cause a stick-slip motion of the carriage component with respect to the base body or the base plate when a fast rising or fast decreasing voltage signal is applied to the piezoelectric stacks.

14. The nanopositioning device of claim 11, wherein the axle further comprises extensions extending from a bottom end of the axle in a direction parallel to the axle, wherein the extensions are thin metallic sheets rigidly connected to the base plate to realize a screw joint between the axle and the base.

15. The nanopositioning device of claim 1 further comprising a base being a support structure placed below the carriage component, wherein the carriage component, the axle, and the base are made of a metallic material selected from the group consisting of Molybdenum (Mo), beryllium copper (BeCu), and phosphor bronze (PhBr); and wherein the ceramic material is Aluminum nitride (AlN) or sapphire.

16. The nanopositioning device of claim 15, wherein the friction interface between the carriage component and the axle enables a bi-directional linear inertial motion of the carriage component relative to the base using a stick-slip mechanism.

17. The nanopositioning device of claim 1, wherein the axle is a cuboid axle with a rectangular cross-section and the axle can be inserted into a rectangular hole gap formed when the front clamp and the rear clamp abut against each other.

18. The nanopositioning device of claim 1, wherein the front clamp and the rear clamp each comprises two screw slots, and wherein the front clamp and the rear clamp are adjustably joined by two spring-loaded screws through the screw slots for controlling a clamping force exerted by the carriage component.

19. A nanopositioning device capable of positioning objects with nanometer scale accuracy with a high thermal conductivity, comprising:
a carriage component comprising a front clamp and a rear clamp; and
an actuator coupled to the carriage component for controlling a position of the carriage component precisely, wherein the actuator comprises piezoelectric stacks and an axle extended from the piezoelectric stacks to the carriage component,
wherein:
the axle comprises a plurality of ceramic plates having a thickness of ≤250 μm;
the plurality of ceramic plates are flat solid plates adhesively attached to the axle for reducing a dissipative friction loss in a stick-slip motion when the carriage component moves along a vertical axis defined by the axle; and
the axle has a diameter that is sufficiently larger than the thickness of the plurality of ceramic plates, thereby a mismatch in thermal expansion coefficient between the plurality of ceramic plates and the axle is negligible.

20. The nanopositioning device of claim 19 further comprising a base being a support structure placed below the carriage component, wherein the carriage component, the axle, and the base are made of a metallic material selected from the group consisting of Molybdenum (Mo), beryllium copper (BeCu), and phosphor bronze (PhBr); and wherein the plurality of ceramic plates are made of Aluminum nitride (AlN) or sapphire.

21. The nanopositioning device of claim 20, wherein the axle further comprises extensions extending from a bottom end of the axle in a direction parallel to the axle, wherein the extensions are thin metallic sheets rigidly connected to the base to realize a screw joint between the axle and the base.

22. The nanopositioning device of claim 19, wherein the axle is a cuboid axle with a rectangular cross-section and the axle can be inserted into a rectangular hole gap formed when the front clamp and the rear clamp abut against each other.

23. The nanopositioning device of claim 22, wherein the plurality of ceramic plates comprises four flat solid plates adhesively attached to four sides of the cuboid axle.

24. The nanopositioning device of claim 19, wherein the plurality of ceramic plates have polished surfaces to form a friction interface with a plurality of internal surfaces of the front clamp and the rear clamp.

25. The nanopositioning device of claim 24, wherein a friction coefficient of the friction interface formed by the carriage component and the plurality of ceramic plates becomes temperature-independent.

26. The nanopositioning device of claim 24, wherein the friction interface between the carriage component and the axle enables a bi-directional linear inertial motion of the carriage component relative to the base using a stick-slip mechanism.
